(19) United States
(12) Patent Application Publication
(10) Pub. No.: US 2019/0358684 A1
(43) Pub. Date: Nov. 28, 2019

(54) METHOD OF CLEANING MASK

(71) Applicant: Sharp Kabushiki Kaisha, Sakai City, Osaka (JP)

(72) Inventor: Chikara NAKAI, Sakai City (JP)

(21) Appl. No.: 16/462,555

(22) PCT Filed: Jun. 7, 2017
(86) PCT No.: PCT/JP2017/021134

§ 371 Date: May 21, 2019

(51) Int. Cl. B08B 7/04; B08B 3/08; B08B 3/10; B08B 7/00

(52) U.S. Cl. CPC B08B 7/04; B08B 3/08; H01L 51/50; B08B 7/0057; B08B 3/10

(57) ABSTRACT

A cleaning apparatus is a mask cleaning apparatus for removing an organic matter adhering to a vapor deposition mask used for forming an organic thin film with a vapor deposition technique, and includes a dry cleaning device for removing the organic matter in a dry process, and a wet cleaning device for removing the organic matter in a wet process.

### Technical Field

The disclosure relates to a cleaning apparatus for removing an organic matter from a mask.

### BACKGROUND ART

PTL 1 discloses a cleaning apparatus that cleans a mask under a completely dry condition without using liquid such as water or a solvent.

### CITATION LIST

### Patent Literature

PTL 1: JP 2011-206720 A (published Oct. 20, 2011).

### SUMMARY

### Technical Problem

Cleaning using the cleaning apparatus disclosed in PTL 1 may not appropriately remove an organic matter depending on irradiation of a mask with atmospheric pressure plasma and an excimer laser.

### Solution to Problem

To solve the problem described above, a cleaning apparatus according to an aspect of the disclosure is a mask cleaning apparatus that removes an organic matter adhering to a mask used for forming an organic thin film with a vapor deposition technique, and that includes a first cleaning device for removing the organic matter in a dry process, and a second cleaning device for removing the organic matter in a wet process.

### Advantageous Effects of Disclosure

According to the aspect of the disclosure, an organic matter adhering to a mask can be appropriately removed, and costs of a chemical solution can be reduced.

### BRIEF DESCRIPTION OF DRAWINGS

FIG. 1A is a flowchart illustrating an example of a method of manufacturing an EL device. FIG. 1B is a flowchart illustrating an example of additional steps in a method of manufacturing a flexible EL device.

FIG. 2A is a cross-sectional view illustrating a configuration example of an EL device of a first embodiment. FIG. 2B is a cross-sectional view illustrating a configuration example during a process of manufacturing the EL device of the first embodiment.

FIGS. 3A to 3C each illustrate a configuration example of a vapor deposition mask used for forming an organic interlayer film or the like. FIG. 3A is a plan view of the vapor deposition mask including a mask sheet, FIG. 3B is a plan view illustrating a manner of stretching the mask sheet, FIG. 3C is a cross-sectional view taken along line c-c of FIG. 3A, and FIG. 3D is a cross-sectional view taken along line f-f of FIG. 3A.

FIG. 4 is a diagram illustrating an outline of a cleaning apparatus according to the first embodiment.

FIG. 5 illustrates a configuration of a dry cleaning device.

FIG. 6 illustrates a configuration of a wet cleaning device.

FIG. 7 is a flowchart illustrating a cleaning method according to a modified example of the first embodiment.

### DESCRIPTION OF EMBODIMENTS

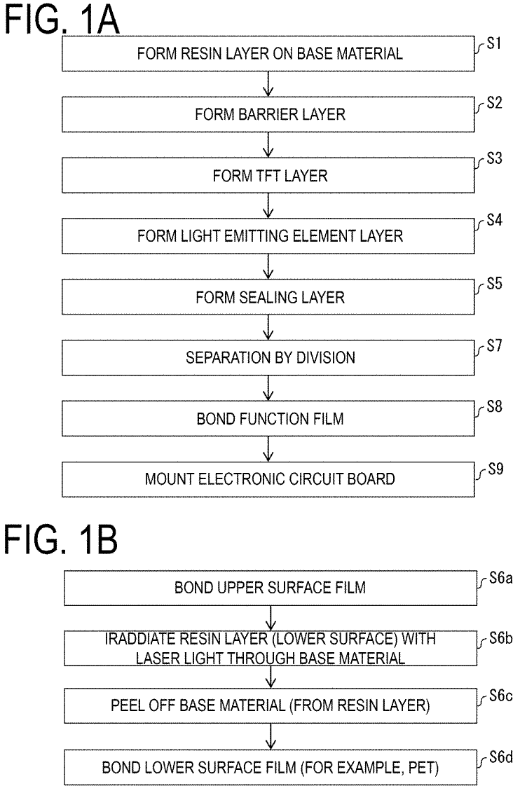

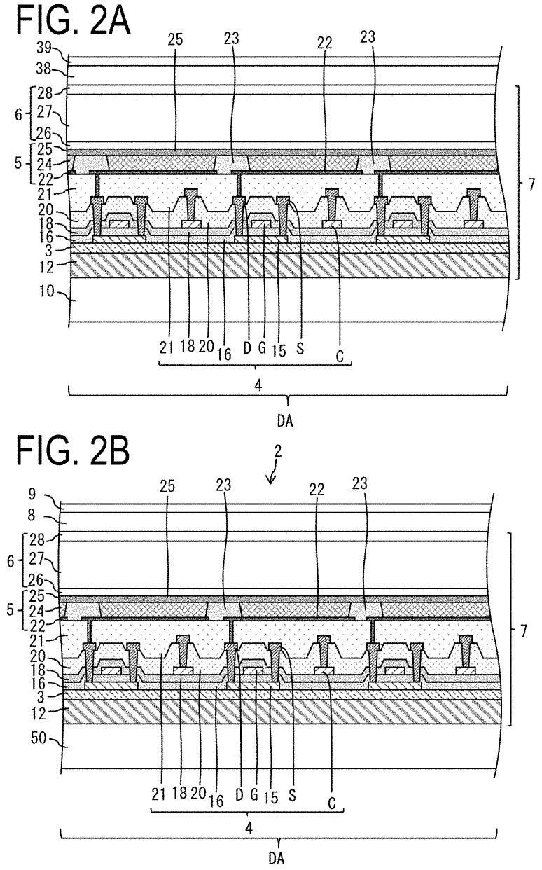

FIG. 1A is a flowchart illustrating an example of a method of manufacturing an EL device. FIG. 1B is a flowchart illustrating an example of additional steps in a method of manufacturing a flexible EL device. FIG. 2A is a cross-sectional view illustrating a configuration example of an EL device of a first embodiment. FIG. 2B is a cross-sectional view illustrating a configuration example during a process of manufacturing the EL device of the first embodiment.

As illustrated in FIGS. 1A and 2A, first, a resin layer 12 is formed on a base material 10 (step S1). Next, a barrier layer 3 is formed (step S2). Next, a TFT layer 4 including a gate insulating film 16, passivation films 18 and 20, and an organic interlayer film 21 is formed (step S3). Next, a light emitting element layer (e.g., an OLED element layer) 5 is formed (step S4). Next, a sealing layer 6 including a first inorganic sealing film 26, a second inorganic sealing film 28, and an organic sealing film 27, is formed to obtain a layered body 7 (step S5). Next, the layered body 7 is divided along with the base material 10 to be split into individual pieces (step S7). Next, a function film 39 is bonded to the layered body 7 with an adhesive layer 38 interposed therebetween (step S8). Next, an electronic circuit board is mounted on an end portion of the TFT layer 4 (step S9). In this way, an EL device 2 illustrated in FIG. 2A is obtained. Each of the above steps is performed by a manufacturing apparatus for the EL device.

When the flexible EL device 2 is manufactured, the layered body 7 (the resin layer 12, the barrier layer 3, the TFT layer 4, the light emitting element layer 5 and the sealing layer 6) is formed in advance on a glass substrate 50, for example, as illustrated in FIGS. 1B and 2B, (steps S1 to S5), and an upper surface film 9 is bonded to the layered body 7 with an adhesive layer 8 interposed therebetween (step S6a). Next, the lower surface of the resin layer 12 is irradiated with a laser light through the glass substrate 50 (step S6b). Here, the lower surface (an interface with the glass substrate 50) of the resin layer 12 changes in properties due to ablation, and a bonding force between the resin layer 12 and the glass substrate 50 decreases. Next, the glass substrate 50 is peeled from the resin layer 12 (step S6c). Subsequently, the base material 10 (e.g., a lower face film made of PET or the like) is bonded to the lower surface of the resin layer 12 with an adhesive layer interposed therebetween (step S6d). Then, processing proceeds to step S7.

Examples of the material of the resin layer 12 include polymide, epoxy, and polyamide and the like. Examples of the material of the base material 10 include polyethylene terephthalate (PET). In the following description, the base material 10 may be referred to as a lower face film 10.

The barrier layer 3 is a layer for preventing moisture and impurities from reaching the TFT layer 4 and the light emitting element layer 5 during usage of the EL device 2. The barrier layer 3 can be composed of, for example, a silicon oxide film, a silicon nitride film, a silicon oxynitride film, or a layered film thereof formed using a chemical vapor deposition (CVD) method.

The TFT layer 4 includes a semiconductor film 15, the gate insulating film 16, a gate electrode G, the passivation films 18 and 20, a capacitance electrode C and a terminal TM, a source electrode S and a drain electrode D, and the organic interlayer film (flattening film) 21. The gate insulating film 16 is formed above the semiconductor film 15. The gate electrode G is formed above the gate insulating film 16. The passivation films 18 and 20 are formed above the gate electrode G. The capacitance electrode C and the terminal TM are formed above the passivation film 18. The source electrode S and the drain electrode D are formed above the passivation film 20. The organic interlayer film 21 is formed above the source electrode S and the drain electrode D. A thin film transistor (TFT) is configured to include the semiconductor film 15, the gate insulating film 16, and the gate electrode G. The TFT layer 4 has a non-active region where a plurality of terminals TM used for connection to the electronic circuit board is formed.

The semiconductor film 15 is formed of low temperature polysilicon (LTPS) or an oxide semiconductor, for example. The gate insulating film 16 can be formed of a silicon oxide (SiOx) film, a silicon nitride (SiNx) film, or a layered film thereof formed using a CVD method, for example. The gate electrode G, the source electrode S, the drain electrode D, and the terminal are formed of a metal single layer film or layered film including at least one of aluminum (Al), tungsten (W), molybdenum (Mo), tantalum (Ta), chromium (Cr), titanium (Ti), and copper (Cu), for example. While FIGS. 2A and 2B each illustrate a TFT using the semiconductor film 15 as a channel with a top gate structure, the TFT may have a bottom gate structure (e.g., in the case where the channel of the TFT is an oxide semiconductor).

The gate insulating film 16, and the passivation films 18 and 20, can be formed of a silicon oxide (SiOx) film, a silicon nitride (SiNx) film, or a layered film thereof, formed using a CVD method, for example. The organic interlayer film 21 can be formed of a coatable photosensitive organic material, such as polymide or acryl, for example. The terminal TM has an edge covered with the organic interlayer film 21.

The light emitting element layer 5 (e.g., an organic light emitting diode layer) includes a first electrode 22 (e.g., an anode electrode) formed above the organic interlayer film 21, an organic insulating film 23 covering an edge of the first electrode 22, an electroluminescent (EL) layer 24 formed above the first electrode 22, and a second electrode 25 formed above the EL layer 24. The first electrode 22, the EL layer 24, and the second electrode layer 25 constitute a light emitting element (e.g., an organic light emitting diode). The organic insulating film 23 in the active region DA functions as a bank (pixel partition) that defines subpixels.

The organic insulating film 23 can be made of a coatable photosensitive organic material such as polymide, or acryl, for example. For example, the organic insulating film 23 can be applied to the active region DA and the non-active region NA by an ink-jet method.

The non-active region NA is provided with a bank-shaped convex member TK surrounding the active region. The convex member TK defines an edge of the organic sealing film 27 (e.g., a film formed by an ink-jet method). The convex member TK is configured to include at least one of the organic interlayer film 21 and the organic insulating film 23, for example.

The EL layer 24 is formed in a region (subpixel region) surrounded by the partition 23c using a vapor deposition or an ink-jet method. When the light emitting element layer 5 is an organic light emitting diode (OLED) layer, the EL layer 24 is formed by layering a hole injection layer, a hole transport layer, a light-emitting layer, an electron transport layer, and an electron injection layer in order from the lower layer side, for example. One or more EL layers 24 may be a shared layer (shared by a plurality of pixels).

The first electrode (anode electrode) 22 is formed by layering of indium tin oxide (ITO) and an alloy including silver (Ag), and has light reflectivity, for example. The second electrode (e.g., a cathode electrode) 25 is a common electrode, and may be formed of a transparent metal such as indium tin oxide (ITO) or indium zinc oxide (IZO).

When the light emitting element layer 5 is an OLED layer, holes and electrons are recombined in the EL layer 24 by drive current between the first electrode 22 and the second electrode 25 to generate excitons, and then the excitons fall to a ground state to emit light.

The light emitting element layer 5 is not limited to the case of constituting an OLED element, and may constitute an inorganic light emitting diode or a quantum dot light emitting diode.

The sealing layer 6 overlies the light emitting element layer 5 and prevents penetration of foreign matters, such as water and oxygen, into the light emitting element layer 5. The sealing layer 6 includes the first inorganic sealing film 26 overlying the organic insulating film 23 and the second electrode 25, an organic sealing film 27 that functions as a buffer film formed above the first inorganic sealing film 26, and the second inorganic sealing film 28 overlying the first inorganic sealing film 26 and the organic sealing film 27.

Each of the first inorganic sealing film 26 and the second inorganic sealing film 28 may be composed of a silicon oxide film, a silicon nitride film, a silicon oxynitride film, or a layered film thereof, formed by a CVD method using a mask. The organic sealing film 27 is a transparent organic insulating film that is thicker than the first inorganic sealing film 26 and the second inorganic sealing film 28, and may be formed of a coatable photosensitive organic material such as polymide or acryl. For example, an ink containing the organic material as described above is applied to the first inorganic sealing film 26 by an inkjet method, and then is cured by ultra violet (UV) radiation.

The function film 39 has an optical compensation function, a touch sensor function, a protection function, for example. When layers having one or more of these functions are layered above the light emitting element layer 5, the function film 39 may be made thinner or removed. The electronic circuit board is an IC chip or a flexible printed circuit board (FPC) mounted on a plurality of terminals TM, for example.

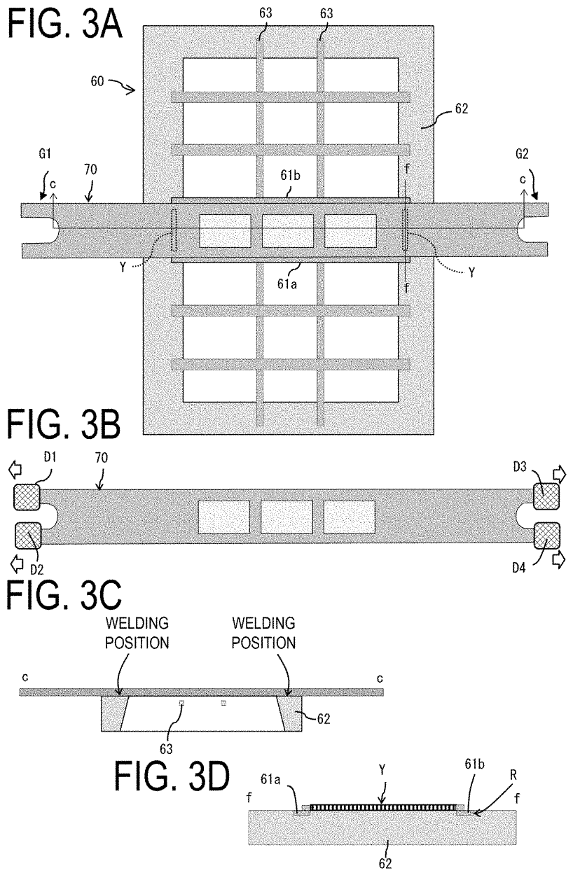

FIGS. 3A to 3C each illustrate a configuration example of a vapor deposition mask 60 (mask) used for forming the organic interlayer film 21 and the like. FIG. 3A is a plan view of the vapor deposition mask 60 including a mask sheet 70, FIG. 3B is a plan view illustrating a manner of stretching the mask sheet 70, FIG. 3C is a cross-sectional view taken along line c-c of FIG. 3A, and FIG. 3D is a cross-sectional view taken along line f-f of FIG. 3A. As illustrated in FIGS. 3A to 3D, the vapor deposition mask 60 according to the first embodiment includes a frame 62, a plurality of support sheets 63 stretched in a lengthwise direction of the frame 62 (a width direction of the mask sheet), a plurality of cover sheets 61a and 61b stretched in a crosswise direction of the frame 62 (a longitudinal direction of the mask sheet 70), and a plurality of the mask sheets 70. While FIGS. 3A and 3B each illustrate only one of the mask sheets 70 for convenience of description, the mask sheets 70 are actually provided by the number of columns of a panel disposed.

A method of forming the vapor deposition mask 60 is as follows. Each of end portions of the support sheet 63 is fitted and welded in a recessed portion provided in the frame 62. In addition, end portions of the respective cover sheets 61a and 61b are fitted into the corresponding recessed portions R provided in the frame 62 so as not to be exposed from an opening of the frame 62, and then are welded. Subsequently, the mask sheet 70 is disposed on the frame 62 so as to overlap with the cover sheets 61a and 61b after its opposite side end portions G1 and G2 are set to the corresponding grippers D1 to D4. As illustrated in FIGS. 3A and 3B, each of the side end portions G1 and G2 has a shape in which its central portion is cut out. Portions across the cutout of the side end portion G1 are inserted into the corresponding grippers D1 and D2, and portions across the cutout of the side end portion G2 are inserted into the corresponding grippers D3 and D4.

Next, tension is applied to the mask sheet 70 by the grippers D1 to D4, and the tension applied by each of the grippers D1 to D4 is independently adjusted to position the mask sheet 70 with respect to the frame 62.

After the positioning is completed, the mask sheet 70 is welded to the frame 62 at its welding portion Y using a laser. Specifically, spot welding is performed at a plurality of places. Accordingly, a plurality of welding spots is formed by melting of the mask sheet 70 and the frame 62, as illustrated in FIGS. 3C and 3D. After the welding is completed, tension caused by the grippers D1 to D4 in the corresponding side end portions G1 and G2 is released, and a portion outside the welding portion Y (an unnecessary portion) in the mask sheet 70 is cut out.

### First Embodiment

### Configuration of Cleaning Apparatus

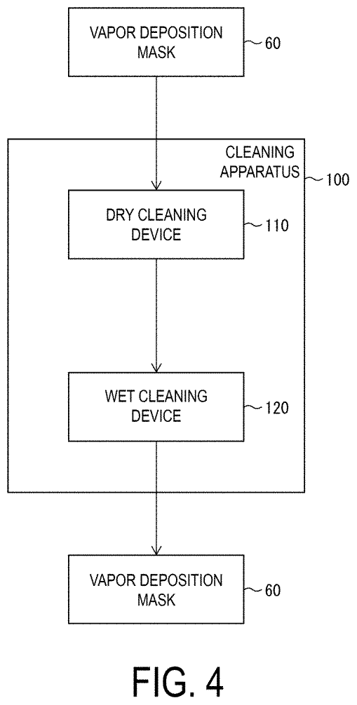

FIG. 4 is a diagram illustrating an outline of a cleaning apparatus 100 (mask cleaning apparatus) according to the present embodiment. The cleaning apparatus 100 is a mask cleaning apparatus that removes an organic matter adhering to a vapor deposition mask 60 used for forming an organic thin film with a vapor deposition technique. As illustrated in FIG. 4, the cleaning apparatus 100 includes a dry cleaning device 110 (first cleaning device), and a wet cleaning device 120 (second cleaning device). Each of the dry cleaning device 110 and the wet cleaning device 120 is capable of cleaning the vapor deposition mask 60 together with the frame 62. The vapor deposition mask 60, which is taken out from a vapor deposition apparatus (not illustrated) to be cleaned, is first cleaned by the dry cleaning device 110 (first cleaning step), and then is further cleaned by the wet cleaning device 120 (second cleaning step). After that, the vapor deposition mask 60 is returned to the vapor deposition apparatus to be reused for vapor deposition of an organic thin film.

The dry cleaning device 110 removes an organic matter adhering to the vapor deposition mask 60 in a dry process. In the present embodiment, the dry cleaning device 110 removes an organic matter from the vapor deposition mask 60 with atmospheric pressure plasma. Materials of the atmospheric pressure plasma include a gas typically used in etching, such as CF₄ or SF₆, for example.

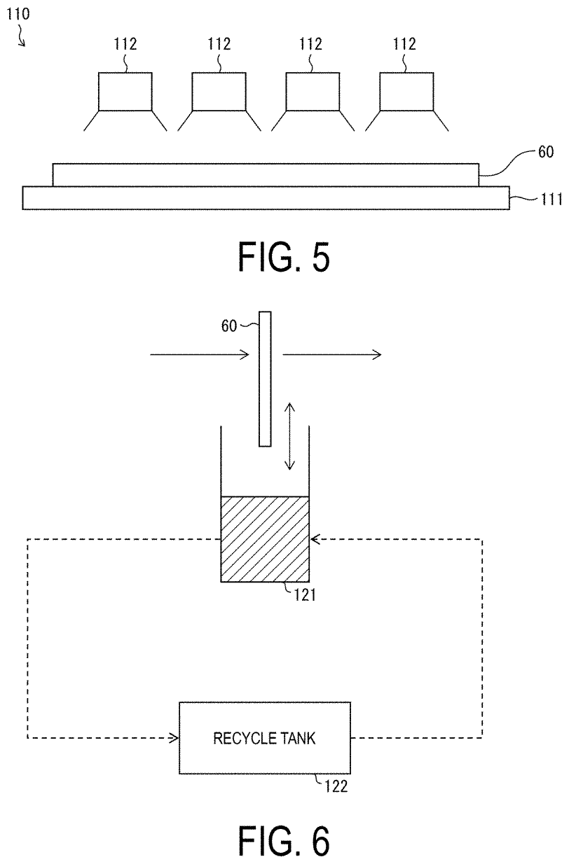

FIG. 5 illustrates a configuration of the dry cleaning device 110. As illustrated in FIG. 5, the dry cleaning device 110 includes a cathode electrode 111 serving as a stage for mounting the vapor deposition mask 60, and a plurality of anode electrodes 112 facing the cathode electrode 111 across the vapor deposition mask 60. The vapor deposition mask 60 is mounted on the cathode electrode 111 so as to allow its surface with an organic matter adhering to face the anode electrodes 112. When voltage is applied between the cathode electrode 111 and the anode electrodes 112 to generate plasma between the cathode electrode 111 and the anode electrodes 112, the organic matter adhering to the vapor deposition mask 60 is removed by the plasma.

FIG. 6 illustrates a configuration of the wet cleaning device 120. The wet cleaning device 120 removes an organic matter adhering to the vapor deposition mask 60 in a wet process. As illustrated in FIG. 6, the wet cleaning device 120 includes a chemical solution tank 121 containing a chemical solution, and a recycle tank 122 for reusing the chemical solution. In the wet cleaning device 120, the vapor deposition mask 60 is supported by an arm (not illustrated) while being parallel to a vertical direction, and then is immersed into the chemical solution in the chemical solution tank 121.

Kinds of chemical solution in the chemical solution tank 121 include an organic solvent-based chemical solution such as N-methylpyrrolidone (NMP). That is, the wet cleaning device 120 removes an organic matter using the NMP in the present embodiment. The NMP is relatively inexpensive as a chemical solution to be used for cleaning an organic matter, and is not particularly excellent in capability of removing an organic matter.

However, the wet cleaning device 120 in the cleaning apparatus 100 removes a small amount of organic matters remaining in the vapor deposition mask 60 after the dry cleaning device 110 removes most of the organic matters adhering to the vapor deposition mask 60. The NMP has adequate capability of removing an organic matter in the wet cleaning device 120 as described above.

Other examples of the chemical solution in the chemical solution tank 121 include a water-based resist stripper and the like. The water-based resist stripper is also relatively inexpensive as a chemical solution to be used for cleaning an organic matter, and has adequate capability of removing an organic matter in the wet cleaning device 120.

The recycle tank 122 is configured to perform treatment of removing an organic matter from the chemical solution in the chemical solution tank 121 after the vapor deposition mask 60 is cleaned. The chemical solution in the chemical solution tank 121 is continuously fed to the recycle tank 122 as indicated by an arrow (broken line) in FIG. 6 so that an organic matter is removed through filtration or the like, for example. Then, the chemical solution is returned into the chemical solution tank 121 to be reused for cleaning of the vapor deposition mask 60. The chemical solution may be fed to the recycle tank 122 from the chemical solution tank 121 for each predetermined period of time or for each predetermined number of cleanings instead of continuous feeding to the recycle tank 122 from the chemical solution tank 121, for example.

### Advantageous Effects

Known cleaning apparatuses and cleaning methods, each of which uses only a wet process, cause the following problems.

Influence on total pitches due to deformation of the vapor deposition mask 60 caused by operating the vapor deposition mask 60 to be immersed into a chemical solution;

Cost of a chemical solution (including cost caused by the amount of chemical solution usage); and

Cost of the chemical solution tank 121 enabling the entire vapor deposition mask 60 to be immersed into a chemical solution.

In addition, when ultrasound is applied to the vapor deposition mask 60 during cleaning, damage to the vapor deposition mask 60 due to the ultrasound may be a problem.

As disclosed in PTL 1, performing the entire cleaning of the vapor deposition mask 60 in a dry process does not cause the problems described above. However, the vapor deposition mask 60 is not always appropriately irradiated with plasma and excimer ultraviolet rays, used in the dry process. Particularly, the plasma may damage the vapor deposition mask 60 itself due to sputtering thereof.

The cleaning apparatus 100 of the present embodiment includes the dry cleaning device 110 and the wet cleaning device 120 as described above. The cleaning apparatus 100 removes most of organic matters adhering to the vapor deposition mask 60 with atmospheric pressure plasma using the dry cleaning device 110. Then, the wet cleaning device 120 removes the organic matters remaining on the vapor deposition mask 60 without being cleaned by the dry cleaning device 110.

The cleaning apparatus 100 is configured such that the dry cleaning device 110 does not need to remove all organic matters with atmospheric pressure plasma. This enables the cleaning apparatus 100 to reduce cleaning time with atmospheric pressure plasma, so that damage to the vapor deposition mask 60 due to the atmospheric pressure plasma can be suppressed.

The cleaning apparatus 100 is also configured such that the wet cleaning device 120 needs to remove only a small amount of organic matters. As a result, the cleaning apparatus 100 enables the wet cleaning device 120 to use an inexpensive chemical solution and reduce the amount of chemical solutions to be used, so that cost of the chemical solutions can be reduced. In addition, it is necessary to remove only a small amount of organic matters, so that the number of the chemical solution tanks 121 each for immersing the vapor deposition mask 60 in a chemical solution can be reduced, and the number of operations of the vapor deposition mask 60 to immerse the vapor deposition mask 60 in the chemical solution can be reduced. This enables the cleaning apparatus 100 not only to reduce cost of the chemical solution tank 121, but also to suppress deformation of the vapor deposition mask 60, due to operation of immersing the vapor deposition mask 60 into a chemical solution.

For example, a known cleaning apparatus configured to clean the vapor deposition mask 60 only in a wet process includes a plurality of chemical solution tanks, and the number of immersing operations identical to the number of the chemical solution tanks is required to immerse the vapor deposition mask 60 into each of the chemical solution tanks. The wet cleaning device 120 only requires the vapor deposition mask 60 to be immersed into one chemical solution tank 121 once. In addition, a small amount of organic matters needs to be removed, so that no ultrasound is required to be applied to the vapor deposition mask 60 to prevent damage to the vapor deposition mask 60 due to the ultrasound.

The cleaning apparatus 100 may further include an oxygen ashing device configured to perform ashing with oxygen plasma in a vacuum, in addition to the dry cleaning device 110 and the wet cleaning device 120, described above. The oxygen ashing device may be provided upstream of the dry cleaning device 110, for example.

The example above describes that each of the dry cleaning device 110 and the wet cleaning device 120 is provided as a cleaning device in the cleaning apparatus 100. However, the dry cleaning device 110 uses atmospheric pressure plasma as described above, and therefore the vapor deposition mask 60 to be cleaned does not need to be held in a vacuum. Thus, a mechanism for generating atmospheric pressure plasma may be provided in a part of a path of transporting the vapor deposition mask 60 from the vapor deposition apparatus to the wet cleaning device 120 to serve as the dry cleaning device 110, for example.

### MODIFIED EXAMPLE

A modified example of the present embodiment will be described below. In the embodiment described above, dry cleaning and wet cleaning are uniformly performed on the vapor deposition mask 60. However, when substances adhering to the vapor deposition mask 60 include no organic matter, only the wet cleaning may be performed without performing the dry cleaning.

In a manufacturing step of an EL device, the vapor deposition mask 60 is separately provided for each vapor deposition source. For example, the same vapor deposition mask 60 is not used for both of a hole transport layer (HTL) and a cathode electrode, so that only a material of the hole transport layer adheres to the vapor deposition mask 60 used for vapor deposition of the hole transport layer. That is, it is determined whether substances adhering include an organic matter, for each individual vapor deposition mask 60.

The individual vapor deposition mask 60 is designated by a lot number, for example, so that a kind of mask, and a history showing which vapor deposition source is used, can be determined. This enables determination whether the substances adhering include an organic matter, based on the lot number.

Thus, a cleaning method of a mask of the present modified example includes a determination step of determining whether substances adhering to the vapor deposition mask 60 used for forming a thin film with a vapor deposition technique include an organic matter. When it is determined that the substances adhering to the vapor deposition mask 60 include an organic matter, a first cleaning step of removing the substances in a dry process, and a second cleaning step of removing the substances in a wet process, are performed. On the other hand, when it is determined that the substances adhering to the vapor deposition mask 60 include no organic matter, only a second cleaning step of removing the substances in a wet process is performed.

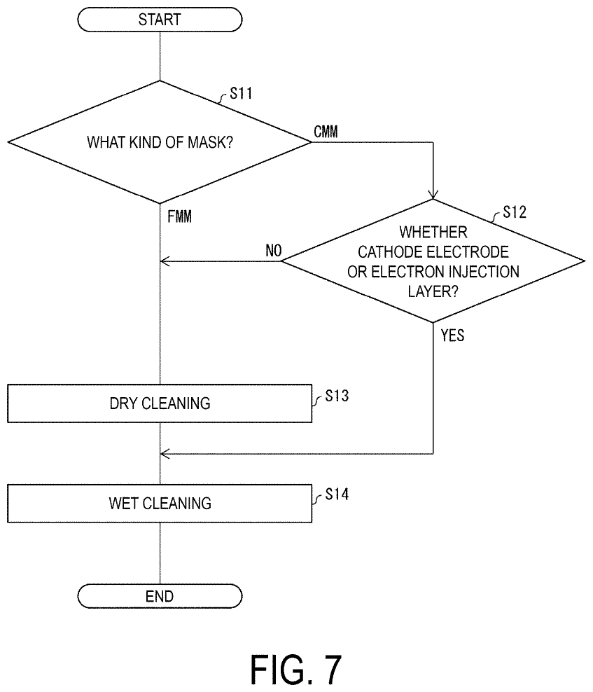

FIG. 7 is a flowchart illustrating a cleaning method according to the present modified example. With reference to FIG. 7, a cleaning method of the vapor deposition mask 60 using a cleaning apparatus 100, according to a modified example of the present embodiment, will be described. In the description below, the cleaning apparatus 100 is configured to determine the vapor deposition mask 60.

First, the cleaning apparatus 100 determines a kind of vapor deposition mask 60 (S11, a determination step). When the kind of vapor deposition mask 60 is a fine metal mask (FMM) (FMM at S11), substances adhering to the vapor deposition mask 60 always include an organic matter. In this case, the cleaning apparatus 100 performs both dry cleaning using a dry cleaning device 110 (S13) and wet cleaning using a wet cleaning device 120 (S14).

When the kind of mask is a common metal mask (CMM) (CMM at S11), the cleaning apparatus 100 further determines whether the vapor deposition mask 60 is a mask to be used for forming a cathode electrode or an electron injection layer (S12, a determination step). When the vapor deposition mask 60 is not the mask to be used for forming a cathode electrode or an electron injection layer (NO at S12), the substances adhering to the vapor deposition mask 60 includes an organic matter. This causes the cleaning apparatus 100 to perform both the dry cleaning (S13) and the wet cleaning (S14), as in the case where the kind of mask is an FMM.

On the other hand, when the vapor deposition mask 60 is the mask to be used for forming a cathode electrode or an electron injection layer (YES at S12), the substances adhering to the vapor deposition mask 60 include no organic matter. In this case, the cleaning apparatus 100 does not perform the dry cleaning (S13), and performs only the wet cleaning (S14).

In the example described above, the cleaning apparatus 100 determines whether the vapor deposition mask 60 is a mask to be used for forming a cathode electrode or an electron injection layer in step S12. However, when there is a layer that does not cause an organic matter to adhere to the vapor deposition mask 60, other than a cathode electrode or an electron injection layer, the cleaning apparatus 100 also determines whether the vapor deposition mask 60 is to be used for forming the layer. For example, when the cleaning apparatus 100 is used in a manufacturing apparatus for an EL device including a hole injection layer made of an inorganic material, the cleaning apparatus 100 determines whether the vapor deposition mask 60 is a mask to be used for forming any one of a cathode electrode, an electron injection layer, and a hole injection layer, in step S12.

### Second Embodiment

A cleaning apparatus 100 of the present embodiment will be described below. For convenience of description, members having the same function as the members stated in the embodiment above are designated by the same reference signs, and the description thereof is eliminated.

In the cleaning apparatus 100 of the present embodiment, a dry cleaning device 110 removes an organic matter from a vapor deposition mask 60 with excimer ultraviolet rays. The excimer ultraviolet rays used in the dry cleaning device 110 preferably have a pulse width of 160 nm or more and 185 nm or less. Specifically, excimer ultraviolet rays with a pulse width of 172 nm can be suitably used, for example. When the vapor deposition mask 60 is irradiated with the excimer ultraviolet rays with the pulse width as described above, heat to be applied to the vapor deposition mask 60 during cleaning thereof can be reduced to suppress deformation of the vapor deposition mask 60 caused by the heat.

The dry cleaning device 110 of the present embodiment also can remove most of organic matters adhering to the vapor deposition mask 60 in a dry process. In particular, in the dry cleaning device 110 of the present embodiment, costs required for a removal process of organic matters include only a cost of a lamp for generating excimer ultraviolet rays. Thus, the cleaning apparatus 100 of the present embodiment can efficiently remove an organic matter adhering to the vapor deposition mask 60 at a relatively low cost, as with the cleaning apparatus 100 of the first embodiment.

### Supplement

A mask cleaning apparatus according to a first aspect removes an organic matter adhering to a mask used for forming an organic thin film with a vapor deposition technique, and includes a first cleaning device for removing the organic matter in a dry process, and a second cleaning device for removing the organic matter in a wet process.

In a second aspect, the first cleaning device removes the organic matter with atmospheric pressure plasma.

In a third aspect, the first cleaning device removes the organic matter with excimer ultraviolet rays.

In a fourth aspect, the excimer ultraviolet rays have a pulse width of 160 nm or greater and 185 nm or less.

In a fifth aspect, the second cleaning device removes the organic matter using NMP or a water-based resist stripper.

A method of cleaning a mask, according to a sixth aspect, is used for removing an organic matter adhering to a mask used for forming an organic thin film with a vapor deposition technique, and includes a first cleaning step of removing the organic matter in a dry process, and a second cleaning step of removing the organic matter in a wet process.

A method of cleaning a mask, according to a seventh aspect, is used for removing substances adhering to the mask used for forming a thin film with a vapor deposition technique, and includes a determination step of determining whether the substances include an organic matter. When it is determined that the substances include the organic matter, a first cleaning step of removing the substances in a dry process, and a second cleaning step of removing the substances in a wet process are performed. When it is determined that the substances include no organic matter, only the second cleaning step is performed.

The disclosure is not limited to each of the embodiments described above, and various modifications may be implemented within a range not departing from the scope of the claims. Embodiments obtained by appropriately combining technical approaches described in each of the different embodiments also fall within the technical scope of the disclosure. Moreover, novel technical features may be formed by combining the technical approaches described in each of the embodiments.

### REFERENCE SIGNS LIST

60 Vapor deposition mask (mask)
100 Cleaning apparatus (mask cleaning apparatus)
110 Dry cleaning device (first cleaning device)
120 Wet cleaning device (second cleaning device)

1-6. (canceled)

7. A method of cleaning a mask, for removing a substance adhering to the mask that is used for forming a thin film with a vapor deposition technique, the method comprising:
a determination step of determining whether the substance includes an organic matter,
wherein when it is determined that the substance includes the organic matter, a first cleaning step of removing the substance in a dry process, and a second cleaning step of removing the substance in a wet process, are performed, and
when it is determined that the substance includes no organic matter, only the second cleaning step is performed.

8. The method of cleaning a mask according to claim 7,
wherein the organic matter is removed with atmospheric pressure plasma in the first cleaning step.

9. The method of cleaning a mask according to claim 7,
wherein the organic matter is removed with excimer ultraviolet rays in the first cleaning step.

10. The method of cleaning a mask according to claim 9,
wherein the excimer ultraviolet rays have a pulse width of 160 nm or more and 185 nm or less.

11. The method of cleaning a mask according to claim 7,
wherein the organic matter is removed using N-methylpyrrolidone (NMP) or a water-based resist stripper in the second cleaning step.
